(19) United States
(12) Patent Application Publication
(10) Pub. No.: US 2026/0214357 A1
(43) Pub. Date: Jul. 23, 2026

(54) IMAGE SENSORS WITH DEVICE ISOLATION LAYERS AND METHOD OF MANUFACTURING THE IMAGE SENSORS

(71) Applicant: Samsung Electronics Co., Ltd., Suwon-si (KR)

(72) Inventors: Fumiya Saitoh, Yokohama (JP); Yoshiharu Kudo, Yokohama (JP)

(21) Appl. No.: 19/376,125

(22) Filed: Oct. 31, 2025

(30) Foreign Application Priority Data
Nov. 19, 2024 (JP) 2024-201277

(51) Int. Cl. H04N 25/773; H10F 39/00; H10F 39/18

(52) U.S. Cl. CPC H04N 25/773; H10F 39/011; H10F 39/18; H10F 39/807; H10F 39/812

(57) ABSTRACT

An image sensor by which degradation of dark count rate (DCR) resulting from multiplication of dark current between an insulating film for device isolation and a semiconductor may be efficiently prevented. The image sensor includes single photon avalanche diode (SPAD) devices, where the SPAD devices include a first SPAD device and a second SPAD device, where the first SPAD device may include: a trench for isolating the first SPAD device from the second SPAD device; a charge-discharging layer formed on a sidewall of the trench and electrically connected to a charge-discharging electrode; and an insulating film formed in the trench and covering the charge-discharging layer.

### CROSS-REFERENCE TO RELATED APPLICATION

This application claims the benefit of Japanese Patent Application No. 2024-201277, filed on Nov. 19, 2024, in the Japanese Patent Office, the disclosure of which is incorporated by reference herein in its entirety.

### BACKGROUND

A single photon avalanche diode (SPAD) is an element configured to multiply charge generated due to photoelectric conversion of incident light through avalanche multiplication and output the charge as electrical signals. The SPAD is capable of detecting particles of light one by one, and thus has high time resolution.

### SUMMARY

The present disclosure relates to an image sensor and a method of manufacturing the image sensor.

In an image sensor in which a plurality of SPAD devices are arranged, the SPAD devices are isolated from each other on a device isolation layer. In this case, dark current may be generated, resulting in a defect level caused due to defects of a crystalline structure at an interface between a semiconductor in which the SPAD devices are formed and an insulating film of the device isolation layer or energy band bending at the interface of the semiconductor caused due to the difference between a work function of the semiconductor and a work function of a metal in the device isolation layer. When the generation of dark current causes an increase in a dark count rate (DCR), detection precision of the image sensor may be degraded. For example, the precision in distance measurement through a Time of Flight (ToF) method by using the SPAD may be degraded.

Some techniques include a hole accumulation region that is connected to an anode, accumulates holes, and traps electrons is formed on a sidewall of an isolation region including a silicon oxide film for isolating devices including avalanche photodiodes. By doing so, excitation of dark current between the device isolation region and silicon may be reduced. However, the dark current may be not sufficiently reduced in some manufacturing processes, and in that case, DCR may increase to a non-negligible degree

Some techniques include a charge-discharging layer having the same conductive type as a conductive type of a charge accumulating layer is formed between Shallow Trench Isolation (STI), which separates pixel transistors that are electrically connected to a photodiode within a pixel, and the charge accumulating layer of the corresponding photodiode. By doing so, electrons generated from the bottom surface of the device isolation region is discharged through the charge-discharging layer to which a positive voltage is applied, and introduction of the photodiode into the charge accumulating layer is prevented, to thereby prevent dark current, which results from the electrons generated from the bottom surface of the device isolation region, from growing in the charge accumulating layer. However, the dark current generated between a pixel isolation wall and silicon may be introduced into a charge-discharging layer of a photodiode and be multiplied, and DCR may increase.

The disclosure provides an image sensor and a method of manufacturing the image sensor, by which degradation of a dark count rate (DCR) resulting from multiplication of dark current generated between an insulating film for device isolation and a semiconductor may be efficiently prevented.

According to an aspect of the disclosure, there is provided an image sensor including a plurality of single photon avalanche diode (SPAD) devices the plurality of SPAD devices may include a first SPAD device and a second SPAD device, where the first SPAD device may include: a trench isolating the first SPAD device from the second SPAD device; a charge-discharging layer on a sidewall of the trench and electrically connected to a charge-discharging electrode; and an insulating film in the trench and covering the charge-discharging layer.

According to an aspect of the disclosure, there is provided a method of manufacturing an image sensor including a plurality of single photon avalanche diode (SPAD) devices. The method may include forming a trench isolating the SPAD device from other SPAD devices; forming a charge-discharging layer on a sidewall of the trench; forming, in the trench, an insulating film covering the charge-discharging layer; exposing a portion of the charge-discharging layer by removing a portion of the insulating film; forming a contact layer at an exposed portion of the charge-discharging layer, where the portion of the insulating film has been removed at the exposed portion of the charge-discharge layer; forming an avalanche region of the SPAD device in a portion surrounded by the trench; exposing a portion of the contact layer by removing another portion of the insulating film; and forming a charge-discharging electrode at the portion of the contact layer.

According to an aspect of the disclosure, there is provided an image sensor including a plurality of single photon avalanche diode (SPAD) devices each SPAD device of the plurality of SPAD devices may include: a trench isolating the SPAD device from neighboring SPAD devices of the plurality of SPAD devices; a charge-discharging layer on a sidewall of the trench; and a semiconductor layer having a first conductive type, where the semiconductor layer is adjacent to the charge-discharging layer and connected to an anode electrode of the SPAD device.

### BRIEF DESCRIPTION OF THE DRAWINGS

Implementations will be more clearly understood from the following detailed description taken in conjunction with the accompanying drawings.

FIG. 1 is a block diagram illustrating a schematic configuration of an image sensor

FIG. 2 is a circuit diagram illustrating an example of a schematic configuration of a single photon avalanche diode (SPAD) pixel.

FIG. 3 is a diagram illustrating a stack structure of a pixel array.

FIG. 4A is a cross-sectional view of a SPAD pixel according to some implementations.

FIG. 4B is a cross-sectional view of a SPAD pixel according to some implementations.

FIG. 4C is a plan view of a SPAD pixel according to some implementations.

FIG. 5 is a diagram illustrating potential corresponding to each position in a path marked with an alternated long-and-short dash line in FIG. 4A.

FIG. 6 is a diagram illustrating potential corresponding to each position in a path marked with a broken line in FIG. 4A.

FIG. 7A is a cross-sectional view for describing a method of manufacturing an image sensor.

FIG. 7B is a plan view for describing a method of manufacturing an image sensor

FIG. 8A is a cross-sectional view for describing a method of manufacturing an image sensor.

FIG. 8B is a plan view for describing a method of manufacturing an image sensor

FIG. 9A is a cross-sectional view for describing a method of manufacturing an image sensor.

FIG. 9B is a plan view for describing a method of manufacturing an image sensor

FIG. 10A is a cross-sectional view for describing a method of manufacturing an image sensor.

FIG. 10B is a plan view for describing a method of manufacturing an image sensor

FIG. 11A is a cross-sectional view for describing a method of manufacturing an image sensor.

FIG. 11B is a plan view for describing a method of manufacturing an image sensor

FIG. 12A is a cross-sectional view for describing a method of manufacturing an image sensor.

FIG. 12B is a plan view for describing a method of manufacturing an image sensor

FIG. 13A is a cross-sectional view for describing a method of manufacturing an image sensor.

FIG. 13B is a plan view for describing a method of manufacturing an image sensor

FIG. 14A is a cross-sectional view for describing a method of manufacturing an image sensor.

FIG. 14B is a plan view for describing a method of manufacturing an image sensor

FIG. 15A is a cross-sectional view for describing a method of manufacturing an image sensor.

FIG. 15B is a plan view for describing a method of manufacturing an image sensor

FIG. 16A is a cross-sectional view for describing a method of manufacturing an image sensor.

FIG. 16B is a plan view for describing a method of manufacturing an image sensor

FIG. 17A is a cross-sectional view for describing a method of manufacturing an image sensor.

FIG. 17B is a plan view for describing a method of manufacturing an image sensor

FIG. 18 is a flowchart illustrating main processes of the method of manufacturing the image sensor corresponding to FIGS. 7A to 17B.

FIG. 19A is a cross-sectional view of a SPAD device according to some implementations.

FIG. 19B is a plan view of a SPAD device according to some implementations.

FIG. 20A is a cross-sectional view of a SPAD device according to some implementations.

FIG. 20B is a plan view of a SPAD device according to some implementations.

FIG. 21A is a cross-sectional view of a SPAD device according to some implementations.

FIG. 21B is a plan view of a SPAD device according to some implementations.

FIG. 21C is a diagram illustrating a potential gradient in a vertical direction of a semiconductor substrate in a charge-discharging layer.

FIG. 22A is a cross-sectional view for describing a method of manufacturing an image sensor.

FIG. 22B is a plan view for describing a method of manufacturing an image sensor

FIG. 23A is a cross-sectional view for describing a method of manufacturing an image sensor.

FIG. 23B is a plan view for describing a method of manufacturing an image sensor

FIG. 24A is a cross-sectional view of a SPAD device according to some implementations.

FIG. 24B is a plan view of a SPAD device according to some implementations.

FIG. 24C is a diagram illustrating potential corresponding to each position of a path marked with an alternated long-and-short dash line in FIG. 24A.

FIG. 25A is a cross-sectional view of a SPAD device according to some implementations.

FIG. 25B is a plan view of a SPAD device according to some implementations.

FIG. 26A is a cross-sectional view of a SPAD device according to some implementations.

FIG. 26B is a plan view of a SPAD device according to some implementations.

FIG. 26C is a diagram illustrating potential gradient in a vertical direction of a semiconductor substrate in a charge-discharging layer.

FIG. 27A is a cross-sectional view of a SPAD device according to some implementations.

FIG. 27B is a plan view of a SPAD device according to some implementations.

FIG. 28A is a cross-sectional view of a SPAD device according to some implementations.

FIG. 28B is a plan view of a SPAD device according to some implementations.

FIG. 28C is a diagram illustrating a potential gradation in a vertical direction of a semiconductor substrate in a charge-discharging layer.

FIG. 29A is a cross-sectional view of a SPAD device according to some implementations.

FIG. 29B is a plan view of a SPAD device according to some implementations.

FIG. 30A is a cross-sectional view of a SPAD device according to some implementations.

FIG. 30B is a plan view of a SPAD device according to some implementations.

FIG. 30C is a diagram illustrating potential gradient in a vertical direction of a semiconductor substrate in a charge-discharging layer.

### DETAILED DESCRIPTION

Hereinafter, an image sensor and a method of manufacturing the image sensor, according to implementations, will be described in detail with reference to the accompanying drawings. Implementations described herein are only examples, and various modification may be made based thereon. Hereinafter, same numeral references in the drawings indicate same components, and sizes of components in the drawings are expressed at a ratio different from actual ratios, for clarity and brevity of description.

Hereinafter, expressions such as “on” or “above” includes being on/under/left/right in a non-contact manner, as well as being directly on/under/left-right in a contact manner.

Terms such as “first” and “second” are used for describing various components, but are used only to distinguish one component from others. Such terms do not limit difference in materials or structures of components.

Components expressed in singular form encompass a plurality of components, unless explicitly indicated otherwise. In addition, the expression “including” a component with a certain portion indicates that other components may be further included, not that the other components are excluded, unless particularly indicated otherwise.

In addition, terms such as “portions” written in the specification indicate units performing one or more functions or operations, and this is implemented by hardware or software or combinations of hardware and software.

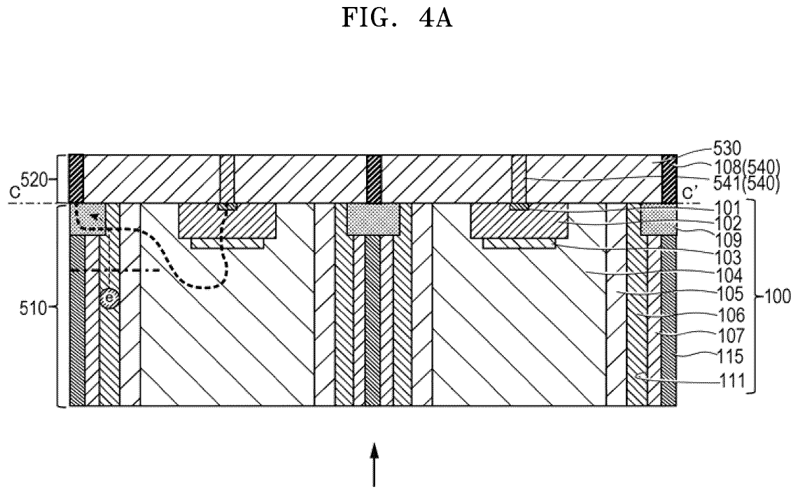

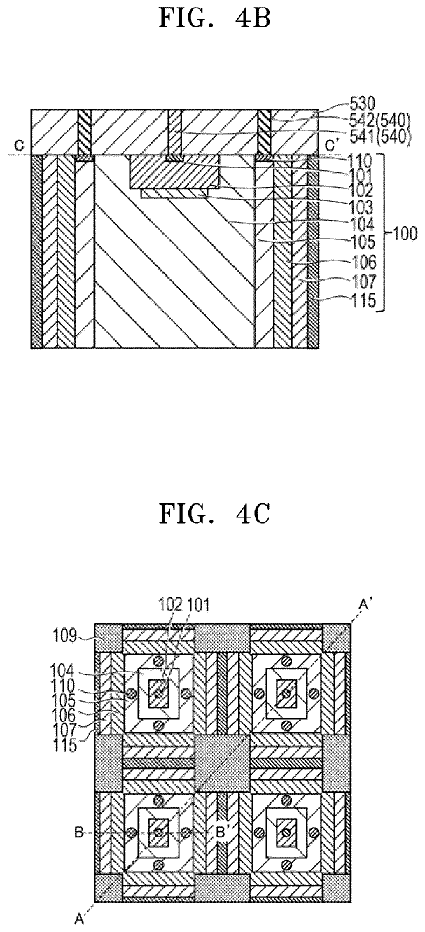

In addition, a cross-sectional view (a) in a cross-section parallel to a surface of a substrate (e.g., FIG. 4C) and a cross-sectional view (b) in a cross-section perpendicular to the surface (e.g., FIG. 4A) of the substrate may be matched by illustrating cutting lines of the cross-sectional views. In this case, a side of a top-down cross-sectional view (a) of a cross-section corresponding to a cutting line in a cross-sectional view (b) may be omitted, and in the cross-sectional view (b), a layer corresponding to the omitted cross-sectional view (a) may be illustrated (e.g., a wiring layer 520 in FIG. 4A).

Hereinafter, for brevity of description, a case where a first conductive type is P-type and a second conductive type is N-type will be described. However, this is only for brevity of description, the first conductive type may also be N-type, and the second conductive type may also be P-type. Hereinafter, a case in which the first conductive-type semiconductor layer is a P-type semiconductor layer and a case where the second conductive-type semiconductor layer is an N-type semiconductor layer will be described. According to some implementations, the first conductive-type semiconductor layer may also be the N-type semiconductor layer. According to some implementations, the second conductive-type semiconductor layer may also be the P-type semiconductor layer.

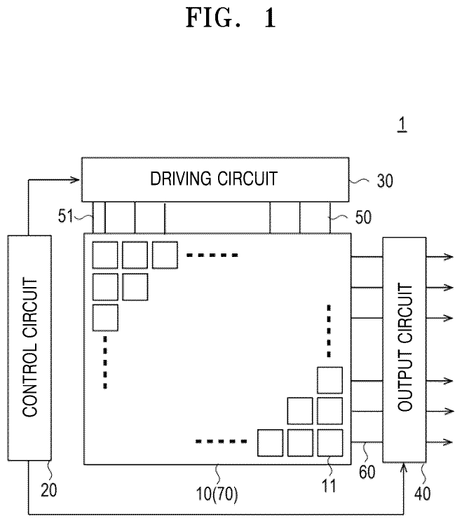

FIG. 1 is a block diagram illustrating a schematic configuration of an image sensor 1. The image sensor 1 may be, for example, the image sensor 1 of a back-side illuminated type. The image sensor 1 may also be the image sensor 1 of a front-side illuminated type. In the image sensor 1 of the back-side illuminated type, a surface opposite to a device formation surface in a semiconductor substrate 510 (see FIG. 4A) will be a light-incident surface. In the image sensor 1 of the front-side illuminated type, the device formation surface will be a light-incident surface. Hereinafter, for brevity of description, the case where the image sensor 1 is the image sensor 1 of the back-side illuminated type will be described. In addition, the device formation surface in the semiconductor substrate 510 may also be referred to as a “front side”, and a surface opposite to the device formation surface in the semiconductor substrate 510 may also be referred to as a “back side”.

The image sensor 1 may include a pixel array 10, a control circuit 20, a driving circuit 30, and an output circuit 40.

The pixel array 10 includes a plurality of single photon avalanche diode (SPAD) pixels 11 arranged in rows and columns. In each SPAD pixel 11, a pixel driving line 50 is connected to each column, and an output signal line 60 is connected to each row. The pixel driving line 50 is connected to an output terminal corresponding to each column of the driving circuit 30. The output signal line 60 is connected to an input terminal corresponding to each row of the output circuit 40.

The driving circuit 30 may include a shift resistor, an address decoder, and the like, and may drive all of the SPAD pixels 11 of the pixel array 10, simultaneously or in rows. The driving circuit 30 may include a circuit configured to apply a quench voltage VQ to be described later to each of the SPAD pixels 11. When the SPAD pixels 11 are driven in column units, the driving circuit 30 may include a circuit configured to apply a selection signal voltage VSEL of each of the SPAD pixels 11 in a selected column. In this case, each SPAD pixel 11 may be selected in response to the selection signal voltage VSEL, a power voltage may be applied only to the selected SPAD pixel 11, and a detection signal VOUT may be output from the corresponding SPAD pixel 11.

The detection signal VOUT output from each of the SPAD pixel 11 is input to the output circuit 40 through each of the output signal lines 60. The output circuit 40 outputs the detection signal VOUT, which is input from each of the SPAD pixels 11, as an image signal.

The control circuit 20 may include a timing generator and the like configured to generate various timing signals and control the driving circuit 30 and the output circuit 40 based on the various timing signals generated in the timing generator.

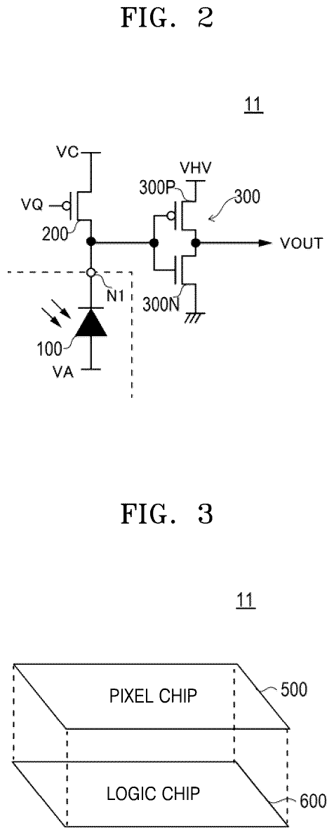

FIG. 2 is a circuit diagram illustrating an example of a schematic configuration of the SPAD pixel 11.

The SPAD pixel 11 includes a SPAD device 100, a quench resistor transistor 200, and an inverter 300. Like in the following description, the SPAD device 100 may be formed in a pixel chip 500 (see FIG. 3), and the quench resistor transistor 200 and the inverter 300 may be formed in a logic chip 600 (see FIG. 3). As the pixel chip 500 and the logic chip 600 are joined by position matching to each of the SPAD pixels 11, each of the SPAD pixels 11 may be formed. In FIG. 2, a connection point at which the SPAD device 100 and the quench resistor transistor 200 are connected to each other due to coupling between the pixel chip 500 and the logic chip 600 is shown as a node N1. In addition, a boundary between the pixel chip 500 and the logic chip 600 is shown as broken lines.

The SPAD device 100 is a light-receiving device, and when photons are incident thereto in a state where a reverse-bias equal to or greater than a breakdown voltage is applied between an anode and a cathode of the SPAD device 100, the SPAD device 100 generates an avalanche current. An anode voltage VA is applied to the anode of the SPAD device 100, and a cathode voltage VC is applied to the cathode of the SPAD device 100 through the quench resistor transistor 200. The anode voltage VA is set, for example, in a range from about −15 V to about −30 V. The cathode voltage VC is set, for example, in a range from about 2 V to about 5 V. As the reverse-bias voltage VSPAD equal to or greater than the breakdown voltage is applied, the SPAD device 100 may operate in a Geiger mode and detect a single photon. The reverse-bias voltage VSPAD is the sum of the absolute value of the anode voltage VA and the absolute value of the cathode voltage VC.

The quench resistor transistor 200 may include, for example, a p-type metal oxide semiconductor (PMOS) transistor. The quench resistor transistor 200 may operate as a quench resistor as a quench voltage VQ supplied from the driving circuit 30 is applied to a gate of the quench resistor transistor 200. The quench resistor transistor 200 may perform a recharge operation of recovering a voltage supplied to the SPAD device 100 to a level of the cathode voltage VC by applying a current corresponding to a voltage drop due to a quench operation.

The current flowing through the SPAD device 100 may be converted to a voltage by the quench resistor transistor 200 and output to the inverter 300.

The inverter 300 is configured as a PMOS transistor 300P and an NMOS transistor 300N are connected in series to each other. Power VHV configured to drive a digital circuit is connected to a source of the PMOS transistor 300P, and a drain of the NMOS transistor 300N is connected to a drain of the PMOS transistor 300P. The drain of the NMOS transistor 300N is connected to the drain of the PMOS transistor 300P, and a source of the NMOS transistor 300N is grounded. Gates of the PMOS transistor 300P and the NMOS transistor 300N are connected to each other, and a point of the connection is an input terminal of the inverter 300. A point of connection between the drain of the PMOS transistor 300P and the drain of the NMOS transistor 300N is an output terminal of the inverter 300. The input terminal of the inverter 300 is connected to a node N1, i.e., a connection point between the SPAD device 100 and the quench resistor transistor 200.

The inverter 300 may convert a voltage being input into a digital signal and output the digital signal as a detection signal VOUT. According to some implementations, a buffer for impedance conversion is connected to the output terminal of the inverter 300, and the detection signal VOUT that is impedance-converted may be output from each of the SPAD pixel 11.

The detection signal VOUT is input to the output circuit 40. The output circuit 40 outputs the detection signal VOUT to the processor, through a time-to-digital converter (TDC) in the case of a Direct Time of Flight (dToF) system and through a counter in the case of a photon counting system. The detection signal VOUT may be input to the processor, and the processor may perform various processes based thereon.

When photons are incident to the SPAD device 100 in a state where the reverse-bias voltage VSPAD equal to or greater than the breakdown voltage is applied to the SPAD device 100 through the quench resistor transistor 200, the avalanche current is generated in the SPAD device 100. As the avalanche current flows through the quench resistor transistor 200, a voltage of the node N1 drops. When the voltage of the node N1 is lower than a threshold voltage of the PMOS transistor 300P of the inverter 300, the PMOS transistor 300P conducts, and thus, the power VHV is output from the inverter 300 as a detection signal at a high level.

Thereafter, when the voltage of the node N1 continuously drops, the voltage applied to the SPAD device 100 becomes less than the breakdown voltage. Therefore, the avalanche current does not flow, and the voltage of the node N1 increases. When the voltage of the node N1 is higher than the threshold voltage of the NMOS transistor 300N of the inverter 300, the NMOS transistor 300N conducts, and a ground voltage is output from the inverter 300 as a detection signal at a low level.

FIG. 3 is a diagram illustrating a stack structure of the pixel array 10.

The SPAD pixels 11 may be arranged in the form of an array and thus may construct the pixel array 10. The SPAD device 100 may construct a device array 70 as the SPAD pixels 11 are arranged in the form of an array. The pixel array 10 has a structure in which a pixel chip 500 and a logic chip 600 are stacked. The pixel chip 500 is a semiconductor chip in which the SPAD device 100 is formed in the form of an array. The logic chip 600 is a semiconductor chip in which the quench resistor transistor 200 and the inverter 300 are formed at a position corresponding to each of the SPAD devices 100. The control circuit 20, the driving circuit 30, and the output circuit 40 may be further formed in the logic chip 600. The above-described buffer configured to impedance-convert the detection signal VOUT may be formed in the logic chip 600.

The pixel chip 500 and the logic chip 600 may be, for example, joined by inter-electronic force by smoothing joint surfaces of the pixel chip 500 and the logic chip 600 and bringing the joint surfaces into contact. More particularly, the pixel chip 500 and the logic chip 600 may be joined as metal pads formed on surfaces (joint surfaces) of the pixel chip 500 and the logic chip 600 are metal-joined.

FIGS. 4A to 4B are cross-sectional views of the SPAD device 100, and FIG. 4C is a plan view of the SPAD device 100. More particularly, FIG. 4A corresponds to a cross-section taken along line A-A′ in FIG. 4C. FIG. 4B corresponds to a cross-section taken along line B-B′ in FIG. 4C. FIG. 4C is a top-plan view of the semiconductor substrate 510 corresponding to a cross-section taken along line C-C′ in FIGS. 4A and 4B.

In FIG. 4A, a straight arrow mark indicates a direction in which light is incident, and a surface, to which the light is incident, is a light-incident surface.

The SPAD device 100 is formed in a plurality on the semiconductor substrate 510 of the pixel chip 500. The semiconductor substrate 510 may be, for example, a silicon substrate. Hereinafter, for brevity of description, the case where the semiconductor substrate 510 is a silicon substrate will be described.

Each of the SPAD devices 100 includes a trench 111 for isolation from another SPAD device 100. The trenches 111 of the plurality of SPAD devices 100, formed in the semiconductor substrate 510, may be connected to one another, thereby forming a grid shape on a plan view from the light-incident surface.

A photoelectric conversion region 104 performs photoelectric conversion on the incident light and generates pairs of electrons and holes (hereinafter, will be also referred to as “charge”). The photoelectric conversion region 104 may be configured as a region doped with an impurity of a relatively low concentration. Hereinafter, for brevity of description, the case in which the photoelectric conversion region 104 is a semiconductor layer doped with an acceptor of a relatively low concentration will be described as an example. Boron (B), for example, is used as the acceptor. The photoelectric conversion region 104 may have a configuration including an intrinsic semiconductor that is not doped with an impurity.

A P-type semiconductor layer 105 is a layer including the acceptor, and may be formed on a sidewall of the trench 111, having a charge-discharging layer 106 between the P-type semiconductor layer 105 and the trench 111. That is, the P-type semiconductor layer 105 may be formed at an opposite side of a first insulating film 107, having the charge-discharging layer 106 between the P-type semiconductor layer 105 and the trench 111. B, for example, may be used as the acceptor. The P-type semiconductor layer 105 may be adjacent to the charge-discharging layer 106. The P-type semiconductor layer 105, to which the reverse-bias voltage VSPAD is applied between the anode electrode 110 and the cathode electrode 101 of the SPAD device 100, may generate an electric field to induce charges generated in the photoelectric conversion region 104 to the avalanche multiplication region. The avalanche multiplication region may be formed, for example, as a P-N junction between the N+type semiconductor region 102 and the P+type semiconductor region 103. The P-type semiconductor layer 105 constructs a first semiconductor layer.

A P+ type semiconductor region 103 is a region including an acceptor of a relatively high concentration. Boron (B), for example, is used as the acceptor. An N+ type semiconductor region 102 is a region including a donor of a relatively high concentration. Phosphorus (P) or arsenic (As) is used as the donor. The P+ type semiconductor region 103 and the N+ type semiconductor region 102 may contact each other and form the PN junction, and may function as a multiplication region that accelerates charge flowing into the P+ type semiconductor region 103 to generate an avalanche current.

The cathode electrode 101, which is a region including a donor of a higher concentration than a concentration of the donor in the N+ type semiconductor region 102, may be in contact with the N+ type semiconductor region 102. The cathode electrode 101 may be in ohmic contact with a cathode wiring 541, i.e., a wiring pattern of a metal layer formed on a wiring layer 520.

The anode electrode 110, which is a region including a donor of a higher concentration than a concentration of the acceptor in the P-type semiconductor layer 105, is in contact with the P-type semiconductor layer 105. The anode electrode 110 may be in ohmic contact with an anode wiring 542, i.e., a wiring pattern of a metal layer formed on the wiring layer 520.

The charge-discharging layer 106, which is an N-type semiconductor layer including a donor of a relatively high concentration, may be formed on a sidewall of the trench 111. The charge-discharging layer 106 formed on the sidewall of the trench 111 may be adjacent to the first insulating film 107 formed in the trench 111. Impurity concentration in the charge-discharging layer 106 may be lower than impurity concentration in the P-type semiconductor layer 105. That is, donor concentration in the charge-discharging layer 106 may be lower than acceptor concentration in the P-type semiconductor layer 105.

The charge-discharging layer 106 may be electrically connected to a charge-discharging electrode 108, having a contact layer 109 between. A charge-discharging voltage may be applied to the charge-discharging layer 106 by the charge-discharging electrode 108, having the contact layer 109 between. Therefore, potential of the charge-discharging layer 106 may be higher than potential of the P-type semiconductor layer 105 to which the anode voltage VA is applied. For example, the potential of the charge-discharging layer 106 is 1 V higher than the potential of the P-type semiconductor layer 105 to which the anode voltage VA is applied. In addition, the charge-discharging voltage may be set to have a potential difference at which breakdown does not occur between the charge-discharging layer 106 and the P-type semiconductor layer 105 to which the anode voltage VA is applied.

An isolator metal layer 115 may be formed of metals. The isolator metal layer 115 is formed of, for example, tungsten (W) and polysilicon (poly Si). The isolator metal layer 115 may be arranged around each of the SPAD pixels 11, may construct a grid in the pixel array 10, and may be formed of, for example, tungsten (W) and polysilicon (poly Si).

The first insulating film 107 covering the charge-discharging layer 106 is formed in the trench 111. As the isolator metal layer 115 and the first insulating film 107 are formed in the trench 111, a deep trench isolation (DTI) may be formed.

The contact layer 109 is formed on a surface of the wiring layer 520 in the semiconductor substrate 510 connected to the charge-discharging electrode 108. The contact layer 109 may be formed of a conductor. The contact layer 109 may be formed of, for example, poly-Si.

The contact layer 109 may be formed in a region including an intersection of the trench 111 having a grid shape and may be shared among the plurality of SPAD devices 100.

The charge-discharging layer 106 may discharge dark current generated at an interface between a silicon oxide (SiO) film and silicon (Si), to thereby prevent the dark current from arriving at the photoelectric conversion region 104. More particularly, the charge-discharging layer 106 may prevent electrons of the dark current generated at an interface between the first insulating film 107 and Si from arriving at the photoelectric conversion region 104.

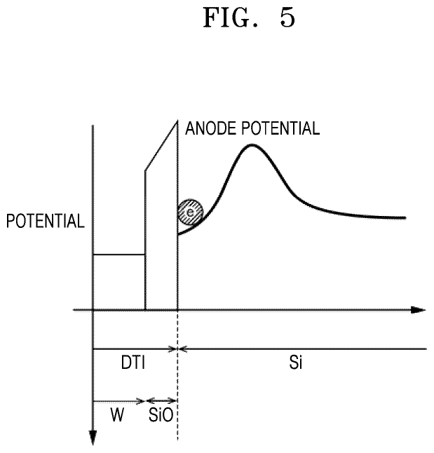

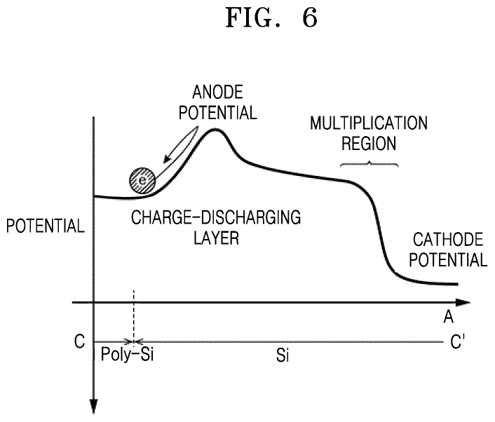

FIG. 5 is a diagram illustrating potential corresponding to each position in a path marked with a long-and-short dash line in FIG. 4A. FIG. 6 is a diagram illustrating potential corresponding to each position in a path marked with a broken line in FIG. 4A.

As illustrated in FIG. 5, potential bending occurs at a boundary between silicon (Si) and a silicon oxide film (SiO) of the first insulating film 107 constructing the DTI together with tungsten (W) of the isolator metal layer 115. This is because the potential of the charge-discharging layer 106 is set higher than the potential (the anode potential) of the P-type semiconductor layer 105 to which the anode voltage VA is applied. Due to such potential bending, electrons as dark current may be generated. In addition, electrons as dark current may also be generated due to a defect level resulting from defects of a crystalline structure in the interface between the silicon oxide film (SiO) and silicon (Si). Like this, the electrons as dark current may be generated at a boundary between the charge-discharging layer 106, which includes silicon (Si), and the first insulating film 107.

As illustrated in FIG. 6, even when the electrons as the dark current are generated at the boundary between the charge-discharging layer 106 and the first insulating film 107, the potential of the charge-discharging layer 106 may be set sufficiently higher than the anode potential by appropriately setting the charge-discharging voltage. For example, by setting the potential of the anode voltage 1 V higher than the potential of the charge-discharging layer 106, a potential barrier of 1 V may be formed against the electrons as the dark current. By doing so, as marked with a curved arrow in FIG. 6, the electrons as the dark current may be prevented from exceeding the anode potential and arriving at the multiplication region of the SPAD device 100. In addition, the generated electrons as the dark current may be discharged from the charge-discharging layer 106 to the outside of the SPAD device 100, having the charge-discharging electrode 108 between.

An anti-reflection film preventing reflection of the incident light may be formed on the back surface (the light-incident surface) of the semiconductor substrate 510 (see FIG. 4A).

A color filter and an on-chip lens corresponding to each of the SPAD devices 100 may be formed on the anti-reflection film. As the color filter, any one of the following may be formed for each of the SPAD devices 100: a color filter configured to selectively transmit light having red (R) wavelength components; a color filter configured to selectively transmit light having green (G) wavelength components; and a color filter configured to selectively transmit light having blue (B) wavelength components. The color filters may be formed in a Bayer array.

As illustrated in FIG. 4A, the wiring layer 520 is formed on a front surface of the semiconductor substrate 510. The wiring layer 520 is constructed with a second insulating film 530 and each of wirings 540. The wirings 540 may be stacked in a plurality of layers having the second insulating film 530 between. In that case, the wirings 540 in the same node, which are adjacent to each other having the second insulating film 530 between, may be connected to each other by a via formed in the second insulating film 530. The wiring 540 may include an anode wiring 542 configured to supply the anode voltage VA to the SPAD device 100 and a cathode wiring 541 configured to supply the cathode voltage VC to the SPAD device 100. In addition, the wiring 540 may include the charge-discharging electrode 108. The anode wiring 542 is connected to the anode electrode 110. The cathode wiring 541 is connected to the cathode electrode 101. The charge-discharging electrode 108 is connected to the contact layer 109. A first connection pad (not shown) is included in the wiring 540. The first connection pad may be exposed on a surface (an upper surface in FIG. 4A) of the wiring layer 520.

The first connection pad may be joined through metal joint with a second connection pad (not shown) exposed on a surface of the logic chip 600. By doing so, the pixel chip 500 and the logic chip 600 may be joined.

The logic chip 600 may be constructed with a substrate and a wiring layer. In this case, a device constructing a logic circuit, including the quench resistor transistor 200 and a transistor constructing the inverter 300, is formed on the substrate. In addition, a wiring for construction of a logic circuit, including a wiring connecting the quench resistor transistor 200 and the inverter 300, or a wiring including a second connection pad is formed on the wiring layer.

Hereinafter, a method of manufacturing the image sensor 1 will be described.

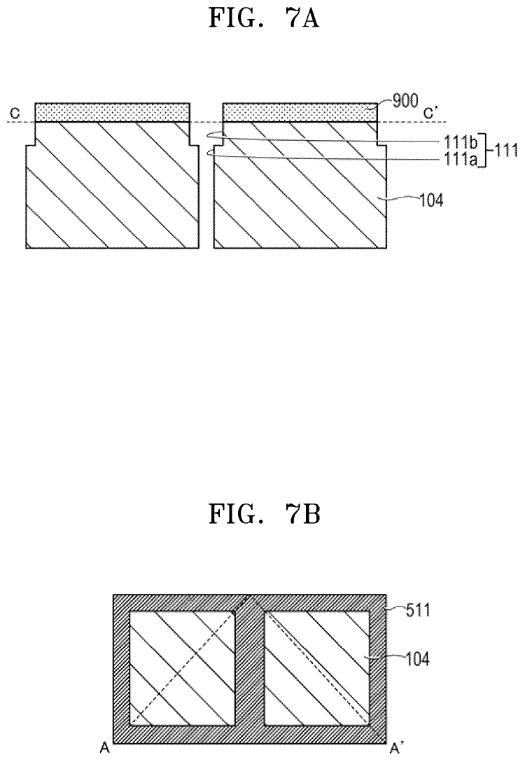

FIGS. 7A to 17B are cross-sectional views and plan views for describing the method of manufacturing the image sensor 1. FIGS. 7A to 17B may correspond to the method of manufacturing the image sensor 1 including the SPAD device 100 illustrated in FIGS. 4A to 4C. In FIGS. 7A to 17B, drawings having common numeral references are drawings for describing the same manufacturing process. In the following drawings, drawings with numbers including A (e.g., FIGS. 7A, 8A, 9A, and the like) correspond to cross-sections taken along line A-A′ in drawings with numbers including B (e.g., FIGS. 7B, 8B, 9B, and the like). In the following drawings, the drawings with numbers including B (e.g., FIGS. 7B, 8B, 9B, and the like) are top-plan views of the semiconductor substrate 510 corresponding to cross-sections taken along line C-C′ in the drawings with numbers including A (e.g., FIGS. 7A, 8A, 9A, and the like).

Referring to FIGS. 7A and 7B, a layer of a hard-mask material 900 is formed on a surface opposite to the light-incident surface of the semiconductor substrate 510, and the hard-mask material 900 is etched by using a mask in which an opening corresponding to a position of the trench 111 is formed. Then, the trench 111 may be formed by etching the semiconductor substrate 510 by using the hard-mask material 900, in which an opening corresponding to the position of the trench 111 is formed, as a mask. More particularly, the trench 111 may be formed by first forming a second trench 111b that is relatively wide and shallow and then forming a first trench 111a that is relatively narrow and deep. By doing so, the trench 111 isolating the photoelectric conversion regions 104 from each other may be formed, and the photoelectric conversion region 104 may be surrounded by silicon 511.

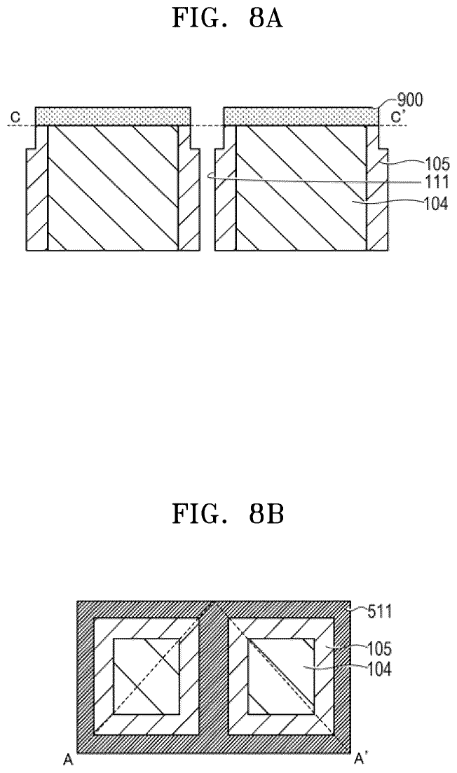

Referring to FIGS. 8A and 8B, the P-type semiconductor layer 105 may be formed on the sidewall of the trench 111 by injecting the acceptor as the impurity into the sidewall of the trench 111 and activating the acceptor through thermal processing. B, for example, may be used as the acceptor.

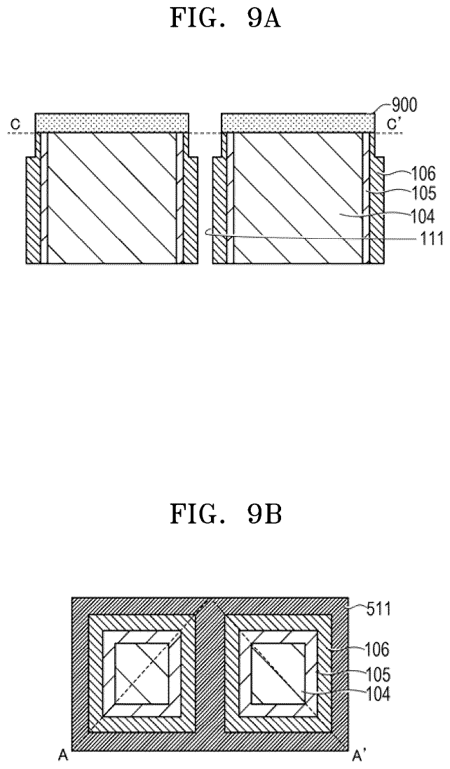

Referring to FIGS. 9A and 9B, the charge-discharging layer 106 adjacent to the P-type semiconductor layer 105 may be formed on the sidewall of the trench 111 by further injecting the donor as the impurity into the sidewall of the trench 111, on which the P-type semiconductor layer 105 has been formed, and by activating the donor through thermal processing.

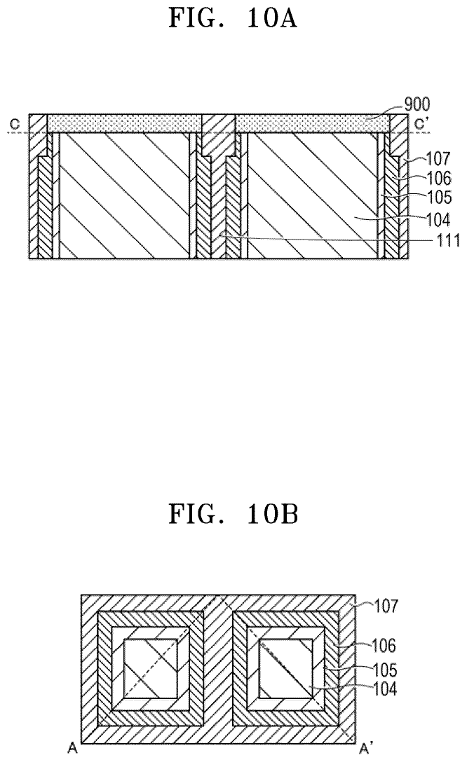

Referring to FIGS. 10A and 10B, the first insulating film 107 is formed in the trench 111. By doing so, the first insulating film 107 covering the charge-discharging layer 106 may be formed in the trench 111.

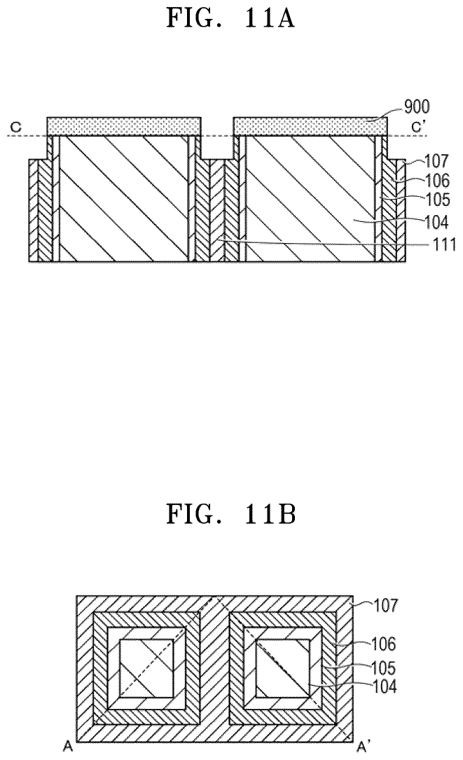

Referring to FIGS. 11A and 11B, a portion of the charge-discharging layer 106 may be exposed by removing a portion of the first insulating film 107. More particularly, the portion of the charge-discharging layer 106 may be exposed by removing a portion of the first insulating film 107 formed inside a second trench 111b.

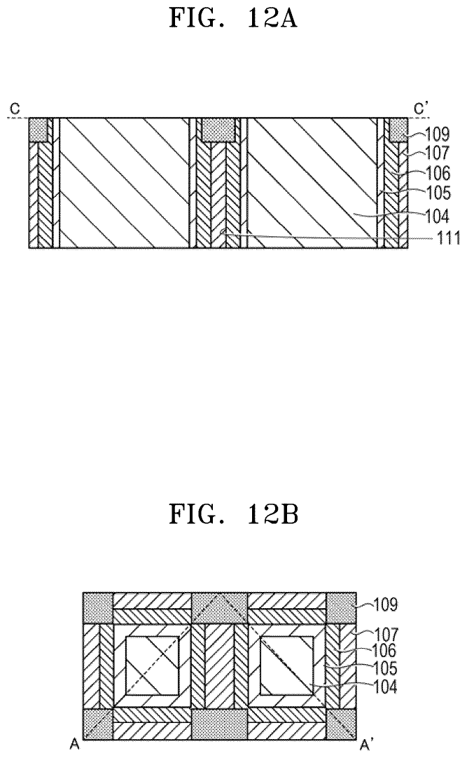

Referring to FIGS. 12A and 12B, the contact layer 109 may be formed by depositing, for example, poly-Si-, at a portion from which the portion of the first insulating film 107 is removed.

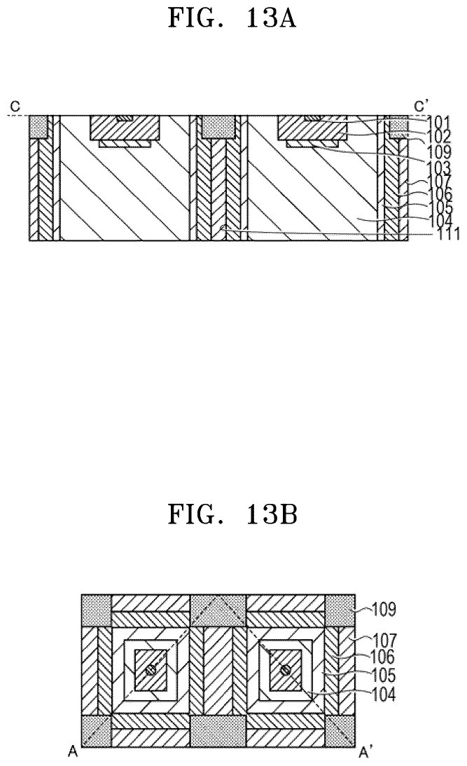

Referring to FIGS. 13A and 13B, the P+ type semiconductor region 103, the N+ type semiconductor region 102, and the cathode electrode 101 may be formed by respectively injecting impurities into portions surrounded by the trench 111 and activating the impurities through a thermal process.

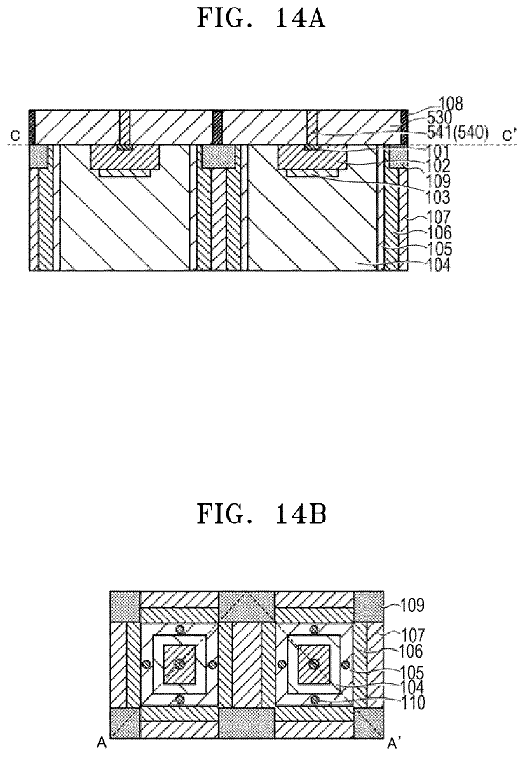

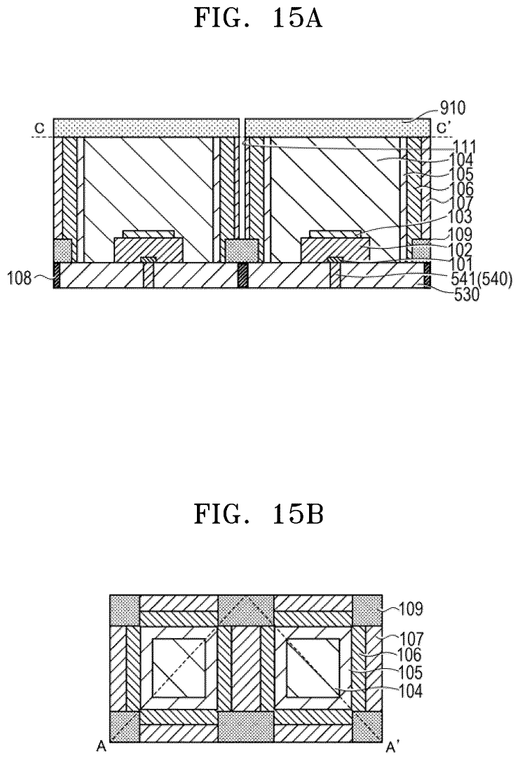

Referring to FIGS. 14A and 14B, the second insulating film 530 may be formed, via holes may be respectively formed at portions of the second insulating film 530 corresponding to the cathode electrode 101, the anode electrode 110, and a contact layer 109, and the cathode wiring 541, the anode wiring 541, and the charge-discharging electrode 108 may be formed by filling the via holes with metals.

Referring to FIGS. 15A and 15B, the semiconductor substrate 510 is flipped to form a layer including a hard-mask material 910 on the back surface of the semiconductor substrate 510, and the hard-mask material 910 is etched by using a mask in which openings corresponding to some positions of the contact layer 109 are formed. In addition, by etching the first insulating film 107 by using the hard-mask material 910, in which the openings corresponding to some positions of the contact layer 109 are formed by etching, a portion of the first insulating film 107 may be removed, and the contact layer 109 may be exposed from the semiconductor substrate 510. More particularly, the portion of the first insulating film 107 may be removed while conserving a portion of the first insulating film 107 covering the charge-discharging layer 106, and the contact layer 109 may be exposed from the semiconductor substrate 510.

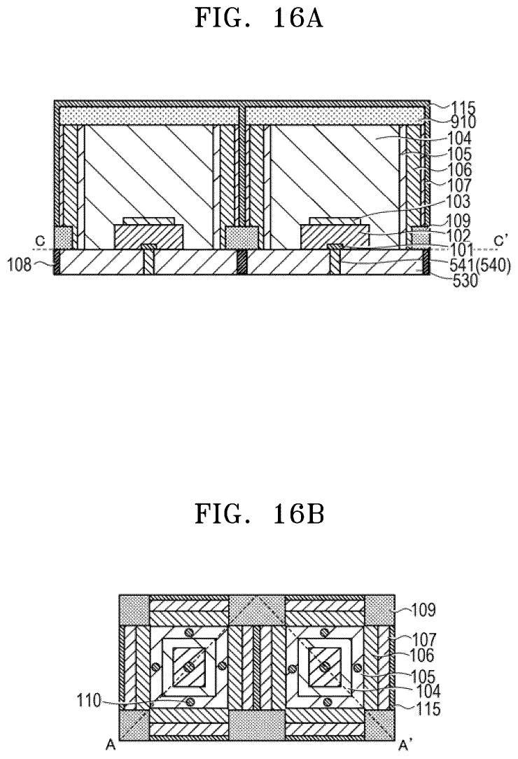

Referring to FIGS. 16A and 16B, a metal may be deposited on the back surface of the semiconductor substrate 510 and the portion from which the portion of the first insulating film 107 has been removed may be filled with metal, by doing so, the isolator metal layer 115 may be formed. Tungsten (W), for example, may be used as the metal.

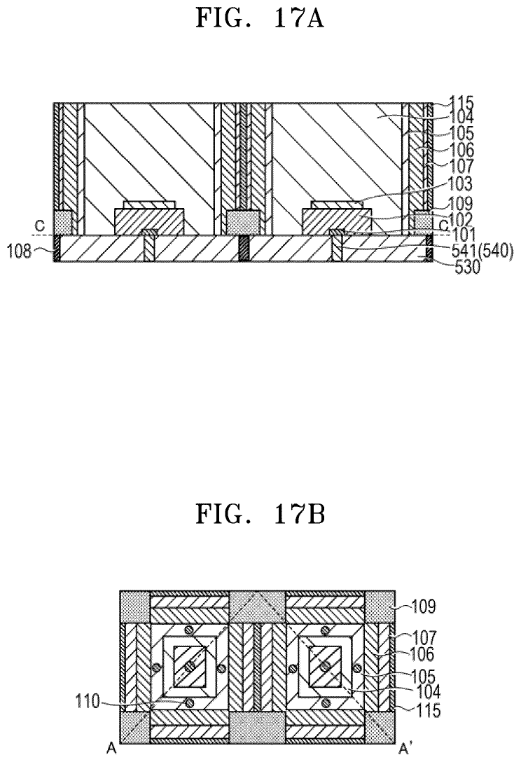

Referring to FIGS. 17A and 17B, the deposited metal may be removed from portions other than the portion from which the portion of the first insulating film 107 has been removed.

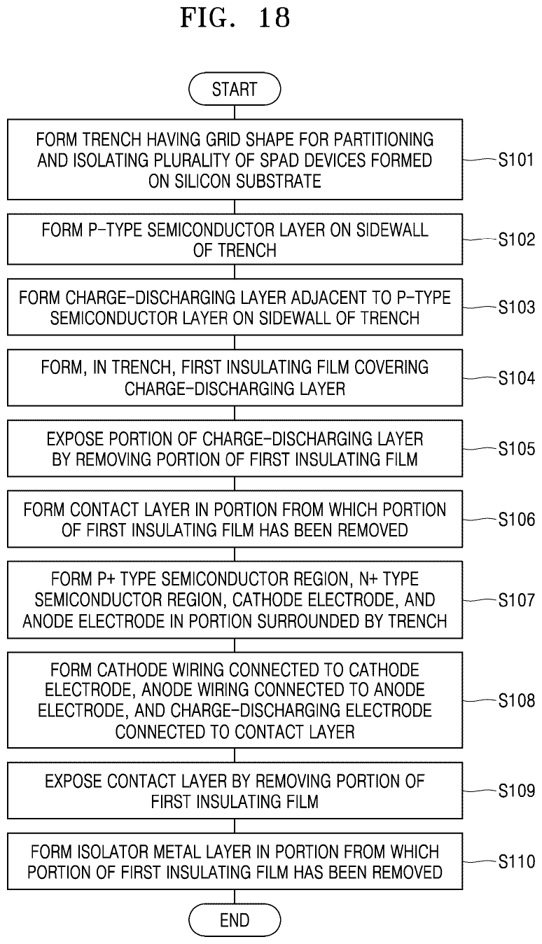

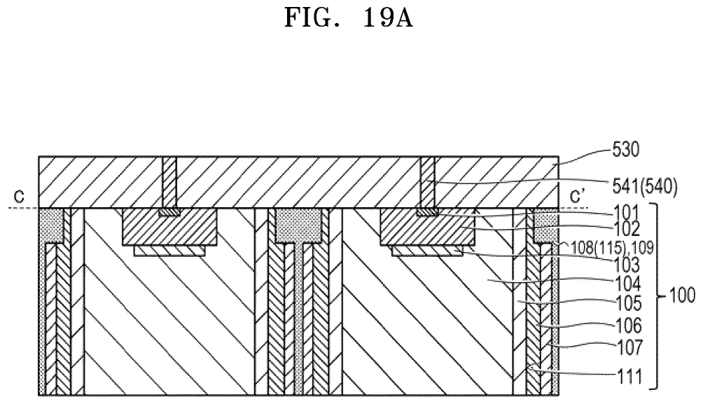

FIG. 18 is a flowchart illustrating main processes of the method of manufacturing the image sensor 1 corresponding to FIGS. 7A to 17B.

The trench 111 having a grid shape is formed in a silicon substrate, i.e., the semiconductor substrate 510, to partition and isolate the plurality of SPAD devices 100 from each other (S101).

Next, the P-type semiconductor layer 105 is formed on the sidewall of the trench 111 (S102).

Next, the charge-discharging layer 106 is formed near the P-type semiconductor layer 105 on the sidewall of the trench 111 (S103).

Next, the first insulating film 107 covering the charge-discharging layer 106 is formed in the trench 111 (S104).

Next, a portion of the charge-discharging layer 106 is exposed by removing a portion of the first insulating film 107 (S105).

Next, the contact layer 109 is formed in a portion from which the portion of the first insulating film 107 is removed in S105 (S106).

Next, the P+ type semiconductor region 103, the N+ type semiconductor region 102, the cathode electrode 101, and the anode electrode 110 are formed in portions surrounded by the trench 111 (S107). Also, the anode electrode 110 may be formed before or after S107.

Next, a cathode wiring 541 connected to the cathode electrode 101 is formed (S108). In addition, at the same time of forming the cathode wiring 541 in S108, the anode wiring 542 connected to the anode electrode 110 and the charge-discharging electrode 108 connected to the contact layer 109 may be formed.

Next, the semiconductor substrate 510 may be flipped, a portion of the first insulating film 107 may be removed, and the contact layer 109 may be exposed from the semiconductor substrate 510 (S109).

Next, the isolator metal layer 115 may be formed in a portion from which the portion of the first insulating film 107 is removed in S109 (S110).

Hereinafter, a modified implementation 1-1 according to a first implementation will be described.

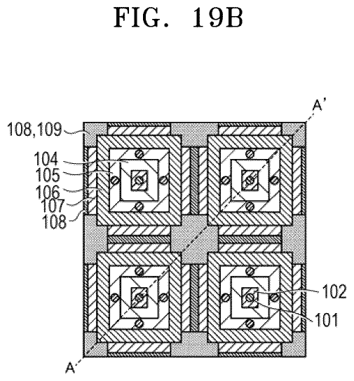

FIGS. 19A and 19B are a cross-sectional view and a plan view of the SPAD device 100, respectively. FIG. 19A corresponds to a cross-section taken along line A-A′ in FIG. 19B. FIG. 19B is a top-plan view of the semiconductor substrate 510 corresponding to a cross-section taken along line C-C′ in FIG. 19A.

In the first implementation, the charge-discharging electrode 108 was arranged on the surface of the substrate (an upper portion in the drawing) and the contact layer 109 was separately arranged, but in the modified implementation 1-1, as shown in FIGS. 19A and 19B, function of the charge-discharging electrode 108 was granted to the isolator metal layer 115 in the first implementation, and the charge-discharging electrode 108 was formed of a conductive material identical to a conductive material in the contact layer 109. For example, the charge-discharging electrode 108 and the contact layer 109 are formed of poly-Si. The charge-discharging electrode 108 and the contact layer 109 may also be integrally formed. In addition, the shape of the contact layer 109 may be a cross shape in a top-plan view from the light-incident surface of the semiconductor substrate 510.

Hereinafter, a modified implementation 1-2 based on the first implementation will be described.

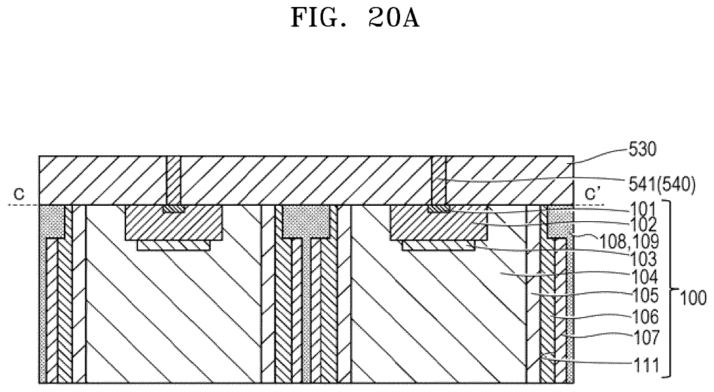

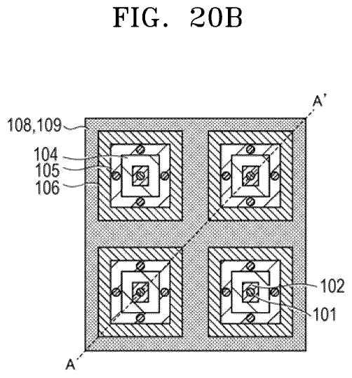

FIGS. 20A and 20B are a cross-sectional view and a plan view of the SPAD device 100, respectively. FIG. 20A corresponds to a cross-section taken along line A-A′ in FIG. 20B. FIG. 20B is a top-plan view of the semiconductor substrate 510 corresponding to a cross-section taken along line C-C′ in FIG. 20A.

In the modified implementation 1-1 with reference to FIGS. 19 and 19B, the contact layer 109 is formed only at an intersection of the trench 111 having the grid shape, but in the modified implementation 1-2, as illustrated in FIGS. 20A and 20B, the contact layer 109 may also be formed in the entire region of top of the trench 111 having the grid shape. By doing so, in a top-plan view from the surface of the semiconductor substrate 510, the contact layers 109 of the SPAD devices 100 may be connected to each other and constructed to surround the charge-discharging layer 106 in the SPAD devices 100. Like in the modified implementation 1-1, the charge-discharging electrode 108 may also be formed of the conductive material identical to the conductive material in the contact layer 109.

Hereinafter, a modified implementation 1-3 based on the first implementation will be described.

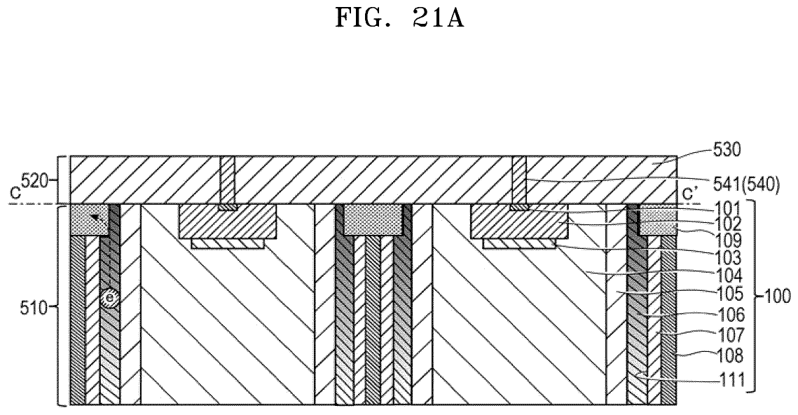

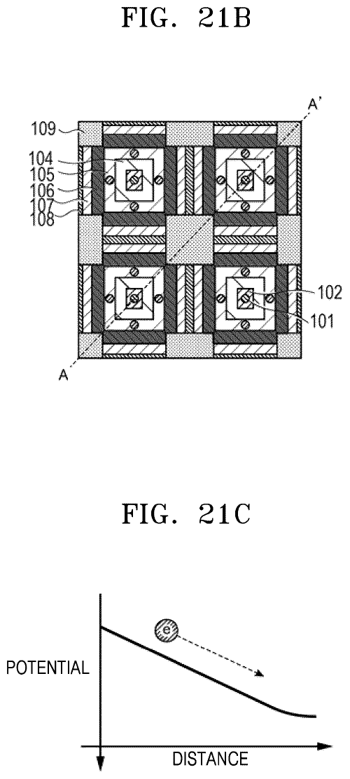

FIGS. 21A and 21B are a cross-sectional view and a plan view of the SPAD device 100, respectively. FIG. 21A corresponds to a cross-section taken along line A-A′ in FIG. 21B. FIG. 21B is a top-plan view of the semiconductor substrate 510 corresponding to a cross-section taken along line C-C′ in FIG. 21A. FIG. 21C is a diagram illustrating potential gradient in the charge-discharging layer 106 in the vertical direction of the semiconductor substrate 510.

As illustrated in FIGS. 21A and 21B, the impurity concentration in the charge-discharging layer 106 may be set higher at a position close to a connection portion connected to the charge-discharging electrode 108 than at a position apart from the connection portion connected to the charge-discharging electrode 108. More particularly, the impurity concentration of the charge-discharging layer 106 is gradually varied such that the concentration at a position close to the contact layer 109 is higher than that at a position apart from the contact layer 109. The potential gradient is not easily generated in the charge-discharging layer 106 when the impurity concentration in the charge-discharging layer 106 is uniform, but by setting the concentration gradient, potential difference may be generated, and the potential gradient with improved charge-discharging ability may be generated.

As illustrated in FIG. 21C, the potential gradient in the vertical direction of the semiconductor substrate 510 may be increased by gradually varying such that impurity concentration in the charge-discharging layer 106 to be higher than at a position close to the contact layer 109 than at a position apart from the contact layer 109. By doing so, the discharge rate of the electrons generated as the dark current may be improved.

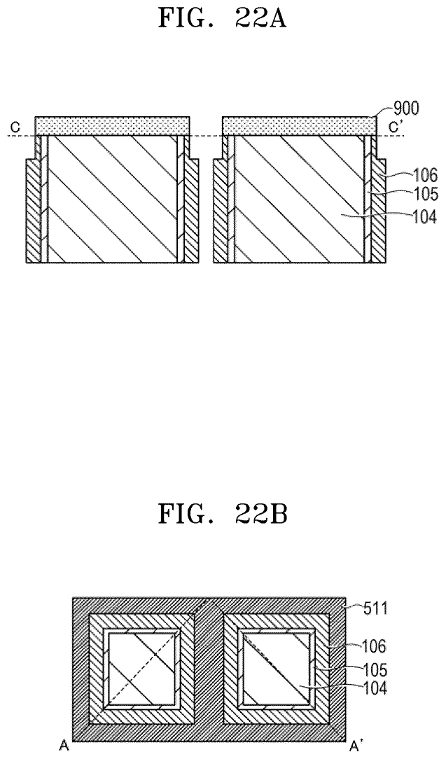

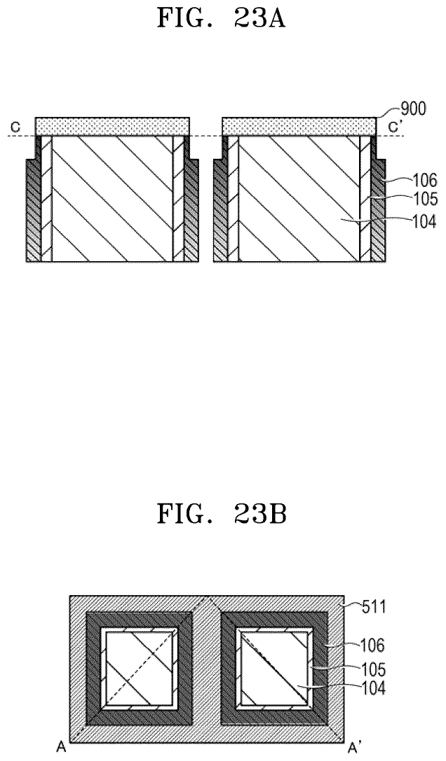

FIGS. 22A to 23B are explanatory diagrams based on a cross-sectional view for describing the method of manufacturing the image sensor 1 with respect to the modified implementation 1-3. In FIGS. 22A to 23B, drawings having common numbers are diagrams for describing the same manufacturing process. Drawings with numbers including A (e.g., FIGS. 22A, 23A, and the like) correspond to cross-sections taken along line A-A in drawings with numbers including B (e.g., FIGS. 22B, 23B, and the like). The drawings with numbers including B (e.g., FIGS. 22B, 23B, and the like) are top-plan views of the semiconductor substrate 510 corresponding to cross-sections taken along line C-C′ in the drawings with numbers including A (e.g., FIGS. 22A, 23A, and the like).

As illustrated in FIGS. 22A and 22B, like in the first implementation, the donor as the impurity is further injected into the sidewall of the trench 111, on which the P-type semiconductor layer 105 is formed, and then is activated through thermal processing, by doing so, the charge-discharging layer 106 is formed adjacent to the P-type semiconductor layer 105 on the sidewall of the trench 111.

As illustrated in FIGS. 23A and 23B, the donor as the impurity is injected into the sidewall of the trench 111 on which the P-type semiconductor layer 105 is formed, with gradual changes in injection energy, and then is activated through thermal processing. By doing so, the charge-discharging layer 106, in which the impurity concentration is higher at the position close to the contact layer 109 than at the position apart from the contact layer 109, may be formed adjacent to the P-type semiconductor layer 105 on the sidewall of the trench 111.

Hereinafter, a second implementation will be described. The difference between the implementation and the first implementation is as follows. In the first implementation, the charge-discharging layer 106 is constructed with N-type semiconductor layers. In the present implementation, by applying a voltage higher in a positive direction than the voltage of the P-type semiconductor layer 105 to the charge-discharging electrode 108, a potential pit (a channel) may be formed in an interface between the P-type semiconductor layer 105 and the first insulating film 107, and a region in which the potential pit is formed may be used as a charge-discharging path 106A. That is, the charge-discharging path 106A is constructed with the potential pit (the channel) generated in the interface. In other aspects, the implementation is identical to the first implementation, and therefore, repeated descriptions will be omitted or briefly given.

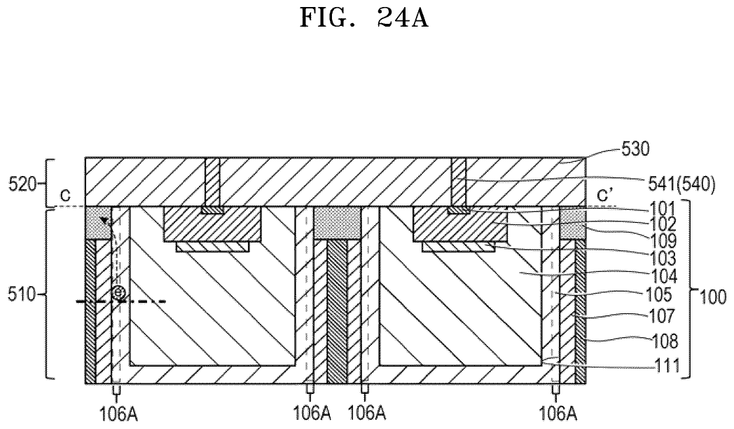

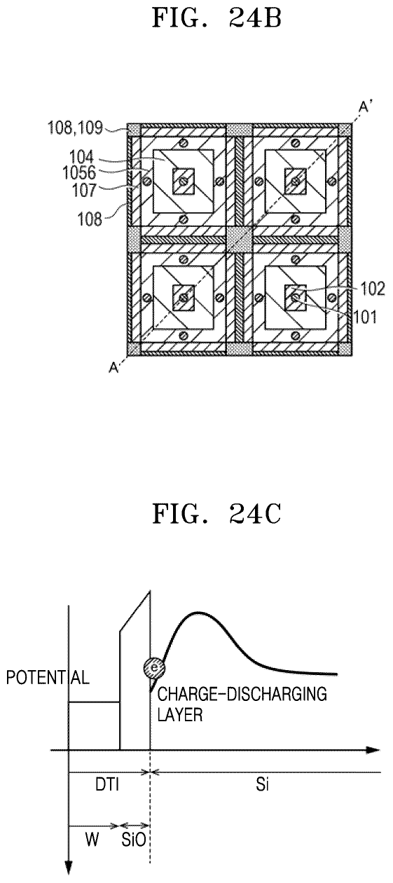

FIGS. 24A and 24B are a cross-sectional view and a plan view of the SPAD device 100, respectively. FIG. 24A corresponds to a cross-section taken along line A-A′ in FIG. 24B. FIG. 24B is a top-plan view of the semiconductor substrate 510 corresponding to a cross-section taken along line C-C′ in FIG. 24A.

The P-type semiconductor layer 105 is connected to the contact layer 109 and is electrically connected to the charge-discharging electrode 108, having the contact layer 109 between the P-type semiconductor layer 105 and the charge-discharging electrode 108. A voltage higher than a voltage of the P-type semiconductor layer 105 in a positive direction is applied to the charge-discharging electrode 108. By such configurations and voltage control, the electrons as the dark current generated at the interface between the P-type semiconductor layer 105 and the first insulating film 107 is transmitted to the charge-discharging electrode 108, having the charge-discharging path 106A and the contact layer 109 between. The charge-discharging path 106A constructs the charge-discharging layer 106. In addition, the anode voltage VA is applied from the anode wiring 542 to the anode electrode 110 arranged on the P-type semiconductor layer 105 (see FIG. 4B).

FIG. 24C is a diagram illustrating potential corresponding to each position of a path marked with an alternated long-and-short dash line in FIG. 24A. As illustrated in FIG. 24C, as a certain charge-discharging voltage is applied to the charge-discharging electrode 108, potential bending occurs at the boundary between the silicon-oxide film (SiO) of the first insulating film 107 and Si. Then, the electrons as the dark current, which are generated at the boundary between the silicon-oxide film (SiO) of the first insulating film 107 and Si, are discharged having the charge-discharging electrode 108 between. In the present implementation, for example, when the anode voltage VA is −20 V, the charge-discharging voltage is set as −18V that is higher by certain potential than −20 V, i.e., the anode voltage VA. As the charge-discharging voltage is appropriately applied, a charge-discharging path 106a is formed at the boundary between the first insulating film 107 and the P-type semiconductor layer 105. The certain potential may be appropriately set through experiments in terms of DCR reduction.

Hereinafter, a third implementation will be described. The difference between the implementation and the first implementation is as follows. In the first implementation, the DTI is formed by forming the charge-discharging electrode 108 and the first insulating film 107 in the trench 111. In the present implementation, the DTI is formed by forming an in-trench anode electrode 112 and the first insulating film 107 in the trench 111, and the in-trench anode electrode 112 and the P-type semiconductor layer 105 are connected to each other by an anode contact 113 formed at a position relatively apart from the cathode electrode 101. In other aspects, the implementation is identical to the first implementation, and therefore, repeated descriptions will be omitted or simplified.

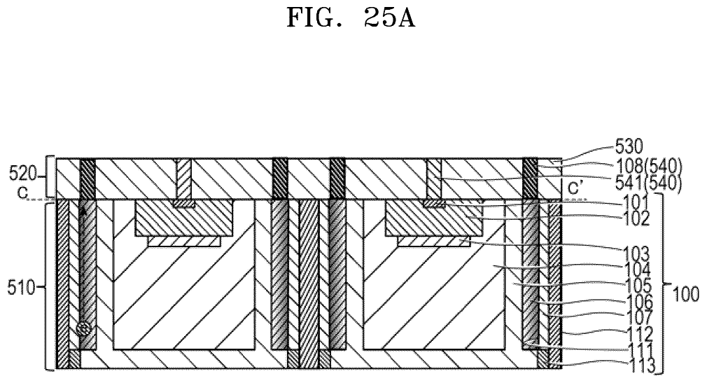

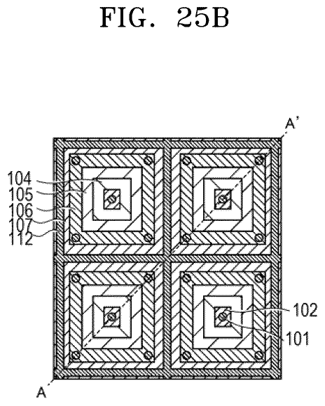

FIGS. 25A and 25B are a cross-sectional view and a plan view of the SPAD device 100, respectively. FIG. 25A corresponds to a cross-section taken along line A-A′ in FIG. 25B. FIG. 25B is a top-plan view of the semiconductor substrate 510 corresponding to a cross-section taken along line C-C′ in FIG. 25A.

As shown in FIGS. 25A and 25B, in the present implementation, the in-trench anode electrode 112 and the first insulating film 107 are formed in the trench 111. In addition, the in-trench anode electrode 112 and the P-type semiconductor layer 105 may be connected to each other through an anode contact formed at a position relatively apart from the cathode electrode 101.

The in-trench anode electrode 112 may be formed of metal. The in-trench anode electrode 112 is formed of, for example, tungsten (W).

The anode contact 113 is formed of, for example, P-type poly-Si doped with the acceptor.

The in-trench anode electrode 112 and the anode contact 113 may also be formed through a method disclosed in Japanese Patent Application No.2024-081552.

The N-type semiconductor layer constructing the charge-discharging layer 106, as donor concentration of the P-type semiconductor layer 105 is relatively low, may be formed such that donor concentration decreases toward the first insulating film 107. The potential gradient in a direction parallel to the semiconductor substrate 510 may be increased by gradually changing donor concentration of the charge-discharge layer 106 such that donor concentration at a position close to the first insulating film 107 is higher than donor concentration at a position apart from the first insulating film 107. Such a structure, in which the donor concentration of the charge-discharging layer 106 is adjusted such that the donor concentration at the position close to the first insulating film 107 is higher than the donor concentration at the position apart from the first insulating film 107, may be implemented, for example, by forming the charge-discharging layer 106 through plasma doping and thermal processing in an operation of forming the charge-discharging layer 106 shown in FIGS. 9A and 9B.

The anode voltage VA may be applied to the in-trench anode electrode 112 and applied to the P-type semiconductor layer 105, having the anode contact 113 between.

The charge-discharging voltage is applied from the charge-discharging electrode 108 to the charge-discharging layer 106.

In the present implementation, by increasing the potential gradient of the charge-discharging layer 106 in the direction parallel to the semiconductor substrate 510, the discharge rate of the electrons generated as the dark current may be improved. In addition, by supplying the anode voltage having the anode contact 113 relatively apart from the cathode electrode 101 between, an electric field between the anode and the cathode may be prohibited, and generation of the electrons as the dark current resulting from a strong electric field may be prohibited.

Hereinafter, a modified implementation 3-1 according to a third implementation will be described.

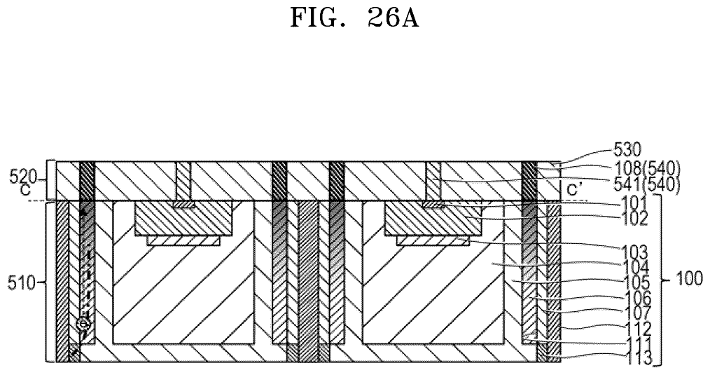

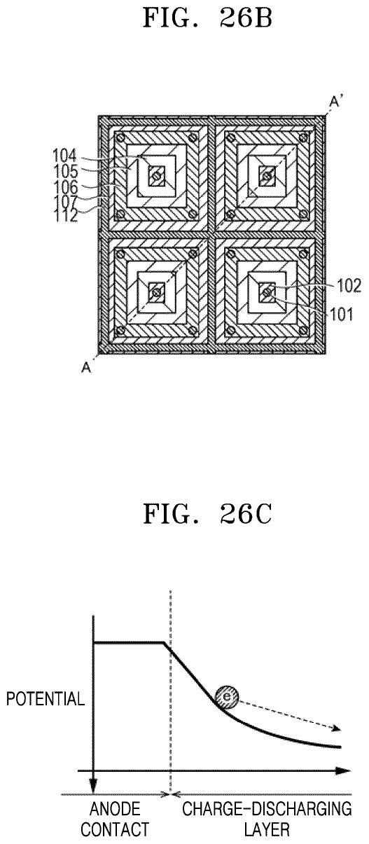

FIGS. 26A and 26B are a cross-sectional view and a plan view of the SPAD device 100, respectively. FIG. 26A corresponds to a cross-section taken along line A-A′ in FIG. 26B. FIG. 26B is a top-plan view of the semiconductor substrate 510 corresponding to a cross-section taken along line C-C′ in FIG. 26A. FIG. 26C is a diagram illustrating potential corresponding to each position of a path mark with an alternated long-and-short dash line in FIG. 26A.

As illustrated in FIGS. 26A and 26B, impurity concentration of the charge-discharging layer 106 may be adjusted such that the impurity concentration at a position close to a connection portion connected to the charge-discharging electrode 108 is higher than the impurity concentration at a position apart from the connection portion connected to the charge-discharging electrode 108. More particularly, the impurity concentration of the charge-discharging layer 106 is gradually changed such that the impurity concentration at the position close to the connection portion connected to the charge-discharging electrode 108 is higher than the impurity concentration at the position apart from the connection portion. The potential gradient is not easily generated when the impurity concentration in the charge-discharging layer 106 is uniform, but by setting concentration gradient, potential difference may be generated, and the potential gradient with increase in charge-discharging ability may be generated.

As illustrated in FIG. 26C, the potential gradient in the vertical direction of the semiconductor substrate 510 may be increased by gradually changing the impurity concentration in the charge-discharging layer 106 to be higher at a position close to the charge-discharging electrode 108, which applies the charge-discharging voltage to the charge-discharging layer 106, than at a position apart from the charge-discharging electrode 108. By doing so, the discharge rate of the electrons generated as the dark current may be improved.

Hereinafter, a fourth implementation will be described. The differences between the present implementation and the first implementation are as follows. In the first implementation, the contact layer 109 is formed on the surface of the semiconductor layer 510, and the contact layer 109 is connected to the charge-discharging electrode 108. In addition, the charge-discharging voltage is applied to the charge-discharging layer 105, having the contact layer 109 between. In the present implementation, a contact layer 114 is formed on a back side of the semiconductor substrate 510, and the contact layer 114 is connected to the charge-discharging electrode 108. In addition, the charge-discharging voltage applied to the charge-discharging electrode 108 is applied to the charge-discharging layer 106, having the contact layer 114 between. In other aspects, the implementation is identical to the first implementation, and therefore, repeated descriptions will be omitted or briefly given.

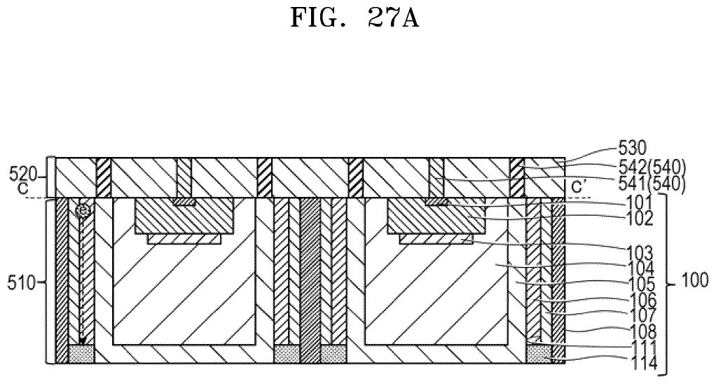

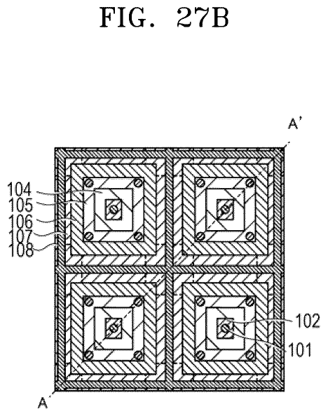

FIGS. 27A and 27B are a cross-sectional view and a plan view of the SPAD device 100, respectively. FIG. 27A corresponds to a cross-section taken along line A-A′ in FIG. 27B. FIG. 27B is a top-plan view of the semiconductor substrate 510 corresponding to a cross-section taken along line C-C′ in FIG. 27A.

As illustrated in FIGS. 27A and 27B, in the present implementation, the contact layer 114 connecting the charge-discharging electrode 108 and the charge-discharging layer 106 is formed on the back surface of the semiconductor substrate 510.

The contact layer 114 is connected to the charge-discharging electrode 108. By doing so, the charge-discharging voltage applied to the charge-discharging electrode 108 is applied to the charge-discharging layer 106 through the contact layer 114.

The contact layer 114 is formed of, for example, N-type poly-Si doped with the donor.

The charge-discharging electrodes 108 of the SPAD devices 100 are formed in the trench 111 having the grid shape, and thus may be connected to each other in the grid shape. Therefore, for example, by applying the charge-discharging voltage to at least a position from the light-incident surface of the semiconductor substrate 510 to the charge-discharging electrode 108 having the grid shape, the applied charge-discharging voltage may be shared between the SPAD devices 100.

Hereinafter, a modified implementation 4-1 according to a fourth implementation will be described.

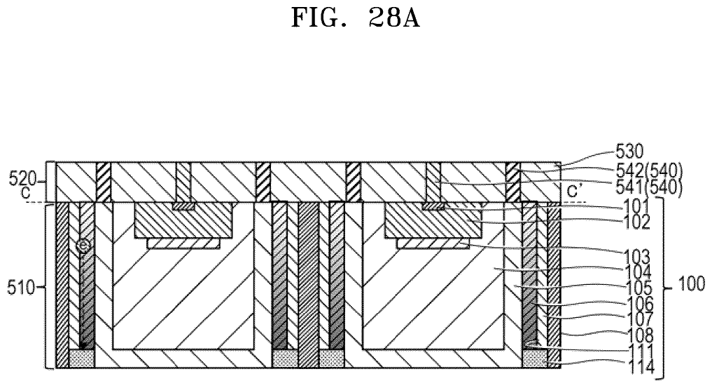

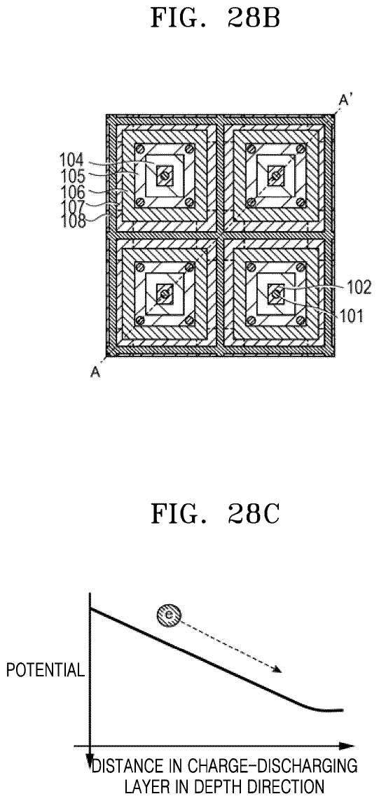

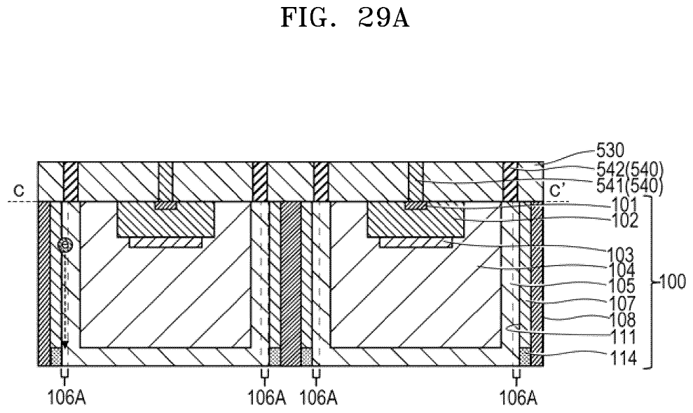

FIGS. 28A and 28B are a cross-sectional view and a plan view of the SPAD device 100, respectively. FIG. 28A corresponds to a cross-section taken along line A-A′ in FIG. 28B. FIG. 28B is a top-plan view of the semiconductor substrate 510 corresponding to a cross-section taken along line C-C′ in FIG. 28A. FIG. 28C is a diagram illustrating the potential gradient in the charge-discharging layer 106 in the vertical direction of the semiconductor substrate 510.

As illustrated in FIGS. 28A and 28B, the impurity concentration of the charge-discharging layer 106 may be adjusted such that the impurity concentration at the position close to the connection portion connected to the charge-discharging electrode 108 is higher than the impurity concentration at the position apart from the connection portion connected to the charge-discharging electrode 108. More particularly, the impurity concentration of the charge-discharging layer 106 is gradually changed such that the impurity concentration at a position close to the contact layer 114 is higher than impurity concentration at a position apart from the contact layer 114.

The impurity concentration of the charge-discharging layer 106 is gradually changed such that the impurity concentration at a position close to the contact layer 114 applying the charge-discharging voltage to the charge-discharging layer 106 is higher than the impurity concentration at a position apart from the contact layer 114. By doing so, the potential gradient of the charge-discharging layer 106 in the vertical direction of the semiconductor substrate 510 may be increased, and discharge rate of the electrons generated as the dark current may be improved.

Hereinafter, a modified implementation 4-2 according to the fourth implementation will be described.

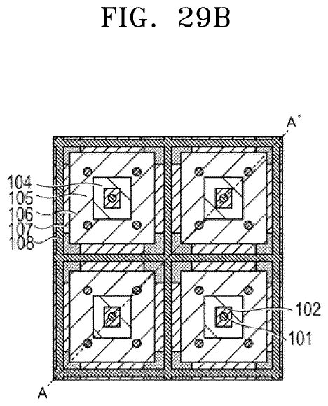

FIGS. 29A and 29B are a cross-sectional view and a plan view of the SPAD device 100, respectively. FIG. 29A corresponds to a cross-section taken along line A-A′ in FIG. 29B. FIG. 29B is a top-plan view of the semiconductor substrate 510 corresponding to a cross-section taken along line C-C′ in FIG. 29A.

The modified implementation corresponds to an example in which a configuration of the second implementation is applied to a configuration of the fourth implementation. More particularly, the charge-discharging layer 106 is configured as a charge-discharging path 106a formed on a P-type semiconductor layer. As illustrated in FIGS. 29A and 29B, the charge-discharging path 106a is formed on the P-type semiconductor layer 105.

The P-type semiconductor layer 105 on which the charge-discharging path 106a is formed is connected to the contact layer 114, and the charge-discharging voltage applied to the charge-discharging electrode 108 is applied to the P-type semiconductor layer 105, having the contact layer 114 between. In addition, the anode voltage VA is applied from the anode wiring 542 to the anode electrode 110 formed on the P-type semiconductor layer 105.

Hereinafter, a modified implementation 4-3 according to the fourth implementation will be described.

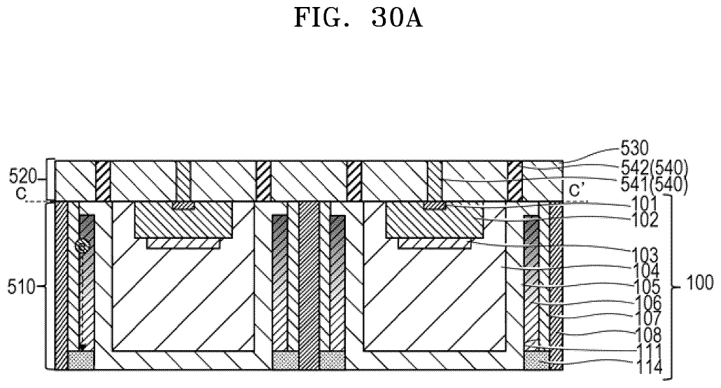

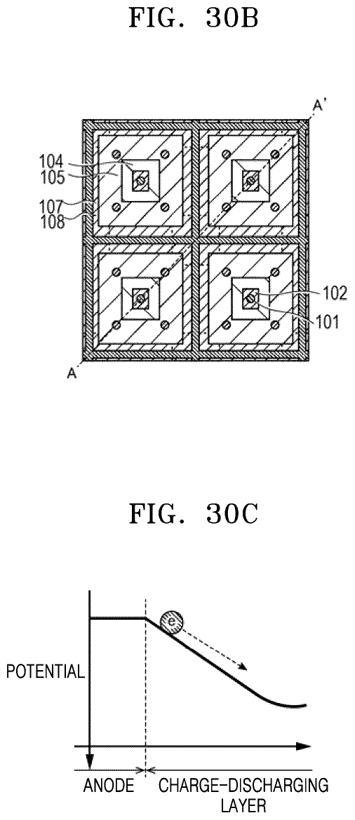

FIGS. 30A and 30B are a cross-sectional view and a plan view of the SPAD device 100, respectively. FIG. 30A corresponds to a cross-section taken along line A-A′ in FIG. 30B. FIG. 30B is a top-plan view of the semiconductor substrate 510 corresponding to a cross-section taken along line C-C′ in FIG. 30A. FIG. 30C is a diagram illustrating the potential gradient in the charge-discharging layer 106 in the vertical direction of the semiconductor substrate 510.

The present modified implementation corresponds to another modified implementation of the charge-discharging layer 106 in the modified implementation 4-1. As illustrated in FIGS. 30A and 30B, by not exposing the charge-discharging layer 106 to the surface of the semiconductor substrate 510, the length of the charge-discharging layer 106 in a depth direction of the semiconductor substrate 510 is set less than in the modified implementation 4-1. By doing so, the potential gradient of the charge-discharging layer 106 in the vertical direction of the semiconductor substrate 510 may be further increased, and the discharge rate of the electrons as the dark current may be further improved.

The implementations of the image sensor described above have the following advantageous effects.

Each of the SPAD devices formed in the substrate includes the trench for isolation from other SPAD devices, the charge-discharging layer formed on a sidewall of the trench and electrically connected to the charge-discharging electrode, and the insulating film formed in the trench and covering the charge-discharging layer. By doing so, degradation of DCR resulting from multiplication of the dark current between the insulating film for device isolation and the semiconductor may be efficiently prevented.

The image sensor may include a first semiconductor layer having a first conductive type at an opposite side of the insulating film, having the charge-discharging layer between, and potential of the charge-discharging layer may be set higher than potential of the first semiconductor layer to which the anode voltage is applied. By doing so, arrival of the electrons as the dark current at the multiplication region of the SPAD device may be easily prevented.

The first semiconductor layer is arranged adjacent to the charge-discharging layer. By doing so, arrival of the electrons as the dark current at the multiplication region of the SPAD device may be easily prevented, while prohibiting increase in the size of the SPAD device.

The charge-discharging layer may be a semiconductor layer having the second conductive type. By doing so, performance of trapping the electrons as the dark current in the charge-discharging layer may be improved.

Impurity concentration in the charge-discharging layer may be set lower than impurity concentration in the first semiconductor layer. By doing so, the degree of depletion of carriers in the charge-discharging layer may be relatively increased, and the performance of trapping the electrons as the dark current in the charge-discharging layer may be further improved.

The impurity concentration in the charge-discharging layer is set higher at the position close to the connection portion connected to the charge-discharging electrode than at the position apart from the connection portion connected to the charge-discharging electrode. By doing so, the potential gradient in the charge-discharging layer may be increased, and the discharge speed of the electrons as the dark current may be improved.

The charge-discharging layer is used as the charge-discharging path in the semiconductor layer having the first conductive type, and potential higher by certain potential than the potential applied to the anode electrode of the SPAD device is applied thereto. By doing so, the arrival of the electrons as the dark current at the multiplication region of the SPAD device may be more easily prevented, while further prohibiting the increase in the size of the SPAD device.

The charge-discharging electrode is formed in the trench. By doing so, crosstalk between the SPAD devices may be prohibited, and by communization of a wiring for application of the charge-discharging voltage for applying the charge-discharging voltage to the charge-discharging electrode in the SPAD devices, a chip area of the image sensor may be reduced.

The contact layer is formed on the front surface of the substrate or the back surface of the substrate. By doing so, the wiring for application of the charge-discharging voltage for applying the charge-discharging voltage may be easily laid out.

The image sensor may include an anode electrode formed in the trench, and therefore, the anode electrode and the first semiconductor layer are in contact with each other on the sidewall of the trench. By doing so, the electric field between the anode and the cathode may be prohibited by forming the anode contact at a position apart from the cathode electrode, and the electrons generated as the dark current resulting from the high electric field may be prohibited.

The implementations described above are only examples, and it would be understood to those skilled in the art that various modifications and other equivalent implementations may be made based thereon. Therefore, the implementations disclosed herein shall be considered in a descriptive sense, not in a limited sense. The scope of right is written in the following claims, and any configurations in an equivalent range thereof will be construed as being included in the claims.

While the disclosure has been particularly shown and described with reference to implementations thereof, it will be understood that various changes in form and details may be made therein without departing from the spirit and scope of the following claims.

As used herein, the term “at least one of” can refer to and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. An image sensor comprising a plurality of single photon avalanche diode (SPAD) devices, wherein
the plurality of SPAD devices comprise a first SPAD device and a second SPAD device, wherein the first SPAD device comprises:
a trench isolating the first SPAD device from the second SPAD device;
a charge-discharging layer on a sidewall of the trench and electrically connected to a charge-discharging electrode; and
an insulating film in the trench and covering the charge-discharging layer.

2. The image sensor of claim 1,
wherein the first SPAD device comprises:
a first semiconductor layer having a first conductive type, wherein the charge-discharging layer is between the first semiconductor layer and the insulating film, and
wherein a potential of the charge-discharging layer is higher than a potential of the first semiconductor layer, the first semiconductor layer being configured to receive an anode voltage.

3. The image sensor of claim 2, wherein the first semiconductor layer is adjacent to the charge-discharging layer.

4. The image sensor of claim 1, wherein the charge-discharging layer comprises a semiconductor layer having a second conductive type.

5. The image sensor of claim 4,
wherein the first SPAD device comprises a first semiconductor layer having a first conductive type, wherein the charge-discharging layer is between the first semiconductor layer and the insulating film, and
wherein an impurity concentration in the charge-discharging layer is lower than an impurity concentration in the first semiconductor layer.

6. The image sensor of claim 4, wherein an impurity concentration in the charge-discharging layer is higher at a first position that is adjacent to a connection portion connected to the charge-discharging electrode than at a second position spaced apart from the connection portion.

7. The image sensor of claim 1, wherein the charge-discharging layer comprises a semiconductor layer having a first conductive type, and
wherein a potential at the charge-discharging layer is higher than a potential at an anode electrode of the first SPAD device.

8. The image sensor of claim 1, wherein the charge-discharging electrode is in the trench.

9. The image sensor of claim 8, comprising a contact layer that connects the charge-discharging layer to the charge-discharging electrode,
wherein the contact layer is in a region where the trench of the first SPAD device intersects with a trench of the second SPAD device, and
wherein the contact layer is shared between the first SPAD device and the second SPAD device.

10. The image sensor of claim 9, wherein
the first SPAD device is on a substrate, and
the contact layer is on a front surface of the substrate or a back surface of the substrate.

11. The image sensor of claim 2, comprising an anode electrode in the trench,
wherein the anode electrode is in contact with the first semiconductor layer on a sidewall of the trench.

12. A method of manufacturing an image sensor comprising a plurality of single photon avalanche diode (SPAD) devices, the method comprising:
forming a trench isolating the SPAD device from other SPAD devices;
forming a charge-discharging layer on a sidewall of the trench;
forming, in the trench, an insulating film covering the charge-discharging layer;
exposing a portion of the charge-discharging layer by removing a portion of the insulating film;
forming a contact layer at an exposed portion of the charge-discharging layer, wherein the portion of the insulating film has been removed at the exposed portion of the charge-discharge layer;
forming an avalanche region of the SPAD device in a portion surrounded by the trench;
exposing a portion of the contact layer by removing another portion of the insulating film; and
forming a charge-discharging electrode at the portion of the contact layer.

13. The method of claim 12, wherein,
forming the charge-discharging layer comprises forming the charge-discharging layer with a concentration that varies based on a distance from a connection portion connected to the charge-discharging electrode.

14. The method of claim 13, comprising:
performing plasma doping and thermal processing to form the charge-discharging layer.

15. An image sensor comprising a plurality of single photon avalanche diode (SPAD) devices, wherein
each SPAD device of the plurality of SPAD devices comprises:
a trench isolating the SPAD device from neighboring SPAD devices of the plurality of SPAD devices;
a charge-discharging layer on a sidewall of the trench; and
a semiconductor layer having a first conductive type, wherein the semiconductor layer is adjacent to the charge-discharging layer and connected to an anode electrode of the SPAD device.

16. The image sensor of claim 15, wherein
the charge-discharging layer has a second conductive type that is different from the first conductive type, and
an impurity concentration in the charge-discharging layer is lower than an impurity concentration in the semiconductor layer.

17. The image sensor of claim 15, wherein
the charge-discharging layer has the first conductive type, and
a potential at the charge-discharging layer is higher than a potential at an anode electrode of the SPAD device.

18. The image sensor of claim 15, wherein an impurity concentration in the charge-discharging layer is variable.

19. The image sensor of claim 15, wherein
the charge-discharging layer is connected to a charge-discharging electrode,
wherein the image sensor comprises a contact layer that connects the charge-discharging layer to the charge-discharging electrode, and
wherein the charge-discharging electrode and the contact layer are integrally formed.

20. The image sensor of claim 15, wherein
the charge-discharging layer is connected to a charge-discharging electrode,
wherein the image sensor comprises a contact layer that connects the charge-discharging layer to the charge-discharging electrode,
wherein the SPAD device is on a semiconductor substrate and wherein the contact layer is on a back surface of the semiconductor substrate, and
wherein a length of the charge-discharging layer in a depth direction is less than a length of the semiconductor substrate in the depth direction.
